(19) United States
(12) Patent Application Publication
(10) Pub. No.: US 2021/0057405 A1
(43) Pub. Date: Feb. 25, 2021

(54) CAPACITIVE APPARATUS AND METHOD FOR PRODUCING THE SAME

(71) Applicant: SHENZHEN GOODIX TECHNOLOGY CO., LTD., Shenzhen (CN)

(72) Inventors: Bin LU, Shenzhen (CN); Jian SHEN, Shenzhen (CN); Bo PI, Shenzhen (CN)

(21) Appl. No.: 17/030,551

(22) Filed: Sep. 24, 2020

Related U.S. Application Data
(63) Continuation of application No. PCT/CN2019/098020, filed on Jul. 26, 2019.

(51) Int. Cl. H01L 27/01

(52) U.S. Cl. CPC H01L 27/016

(57) ABSTRACT

Embodiments of the application provide a capacitive apparatus and a method for producing the same. The capacitive apparatus includes at least one capacitor; where the at least one capacitor includes at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient. Using a principle of positive and negative cancellation, when the at least one capacitor is regarded as a whole, a voltage coefficient and/or a temperature coefficient thereof may be zero or close to zero. Thus, when a bias voltage or a temperature of the at least one capacitor changes, a capacitance value thereof does not change or changes slightly, thereby effectively ensuring the performance of the capacitive apparatus.

### CROSS REFERENCE TO RELATED APPLICATIONS

This application is a continuation of International Application No. PCT/CN2019/098020, filed on Jul. 26, 2019, the disclosure of which is hereby incorporated by reference in its entirety.

### TECHNICAL FIELD

The present disclosure relates to the field of capacitors, and in particular, to a capacitive apparatus and a method for producing the same.

### BACKGROUND

A capacitor may play a role of bypassing, filtering, decoupling, or the like in a circuit, which is an indispensable part of ensuring a normal operation of the circuit. A capacitance value of an actually produced capacitor changes with the magnitude of a bias voltage across both ends thereof or a temperature thereof.

Specifically, the change of the capacitance value of the capacitor with the bias voltage may be characterized by the following equation:

C(V)=C₀(α·V²+β·V+1)

C₀ represents a capacitance value of a capacitor under a bias voltage of zero volts (V), α is a secondary voltage coefficient of the capacitor, and β is a primary voltage coefficient of the capacitor, which is also referred to as a linear coefficient.

Similarly, the change of the capacitance value of the capacitor with the temperature may be characterized by the following equation:

C(T)=C₂₅(γ·(T−25)+1)

C₂₅ is a capacitance value of the capacitor at 25 degrees Celsius (° C.), and γ is a temperature coefficient of the capacitor.

The voltage coefficient and the temperature coefficient of the capacitor may be positive or negative according to different dielectric materials used.

In the prior art, a material with a positive voltage coefficient and a material with a negative voltage coefficient are generally mixed uniformly to form a dielectric material with a voltage coefficient close to zero, and/or a material with a positive temperature coefficient and a material with a negative temperature coefficient are generally mixed uniformly to form a dielectric material with a temperature coefficient close to zero, and thus a capacitor with a voltage coefficient and/or a temperature coefficient close to zero is produced to improve performance of the capacitor. For example, NP0 type multilayer ceramic capacitors (MLCC).

However, it is difficult to produce a capacitor with a coefficient close to zero by mixing materials with different coefficients, due to higher process requirements.

Therefore, there is an urgent need in the art for a new capacitor with a voltage coefficient and/or a temperature coefficient close to zero.

### SUMMARY

Embodiments of the present disclosure provide a capacitive apparatus and a method for producing the same, which could reduce a voltage coefficient and/or a temperature coefficient of the capacitive apparatus.

In a first aspect, a capacitive apparatus is provided, including:

at least one capacitor;

where the at least one capacitor includes at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient.

The positive voltage coefficient of the first dielectric layer cancels out the negative voltage coefficient of the second dielectric layer, so that a voltage coefficient of the at least one capacitor may be zero or close to zero. Similarly, the positive temperature coefficient of the first dielectric layer cancels out the negative temperature coefficient of the second dielectric layer, so that a temperature coefficient of the at least one capacitor may be zero or close to zero. That is, using a principle of positive and negative cancellation, when the at least one capacitor is regarded as a whole, a voltage coefficient and/or a temperature coefficient thereof may be zero or close to zero.

Thus, when a bias voltage or a temperature of the at least one capacitor changes, a capacitance value thereof does not change or changes slightly, thereby effectively ensuring the performance of the capacitive apparatus.

In some possible embodiments, the positive voltage coefficient of the first dielectric layer and the negative voltage coefficient of the second dielectric layer enable a voltage coefficient of the at least one capacitor to be zero or close to zero; and/or the positive temperature coefficient of the first dielectric layer and the negative temperature coefficient of the second dielectric layer enable a temperature coefficient of the at least one capacitor to be zero or close to zero.

In some possible embodiments, the at least one capacitor includes:

at least two capacitors connected in parallel;

where the at least two capacitors include at least one first capacitor and at least one second capacitor, and the first capacitor has a positive voltage coefficient and the second capacitor has a negative voltage coefficient, so that a voltage coefficient of the at least two capacitors is zero or close to zero; and/or the first capacitor has a positive temperature coefficient and the second capacitor has a negative temperature coefficient, so that a temperature coefficient of the at least two capacitors is zero or close to zero.

That is, the voltage coefficient of the first capacitor cancels out the voltage coefficient of the second capacitor and/or the temperature coefficient of the first capacitor cancels out the temperature coefficient of the second capacitor, so that when the at least two capacitors connected in parallel are regarded as a whole, a voltage coefficient and/or a temperature coefficient thereof is zero or close to zero.

Thus, when a bias voltage or a temperature of the at least two capacitors changes, a capacitance value thereof does not change or changes slightly, thereby effectively ensuring the performance of the capacitive apparatus.

In some possible embodiments, the first dielectric layer includes a first silicon dioxide (SiO₂) layer, a second SiO₂ layer and a first hafnium oxide (HfO₂) layer, where the first HfO₂ layer is disposed between the first SiO₂ layer and the second SiO₂ layer; and the second dielectric layer includes a third SiO₂ layer, a fourth SiO₂ layer and an yttrium oxide (Y₂O₃) layer, where the Y₂O₃ layer is disposed between the third SiO₂ layer and the fourth SiO₂ layer.

As a voltage coefficient of Y₂O₃ is negative and a voltage coefficient of HfO₂ is positive, Y₂O₃ and HfO₂ are respectively used as dielectric layers in two capacitors, so that when the two capacitors are regarded as a whole, a voltage coefficient thereof may be zero or close to zero.

Thus, when a bias voltage or a temperature of the two capacitors changes, a capacitance value thereof does not change or changes slightly, thereby effectively ensuring the performance of the capacitive apparatus.

In addition, Y₂O₃ and HfO₂ belong to high dielectric constant (high-k) materials, and a band gap thereof is small, which easily causes excessive leakage of the capacitor. Therefore, SiO₂ with a wide band gap is placed on upper and lower surfaces of the high-k materials, which could reduce the leakage of the capacitor and ensure the comprehensive performance of the capacitor.

In some possible embodiments, a number of the at least one first capacitor is equal to a number of the at least one second capacitor.

In some possible embodiments, the at least one capacitor includes:

a third capacitor, where dielectric layers of the third capacitor include the first dielectric layer and the second dielectric layer, so that a voltage coefficient and/or a temperature coefficient of the third capacitor is zero or close to zero.

That is, the voltage coefficient of the first dielectric layer cancels out the voltage coefficient of the second dielectric layer, and/or the temperature coefficient of the first dielectric layer cancels out the temperature coefficient of the second dielectric layer, so that when the dielectric layers of the third capacitor are regarded as a whole, a voltage coefficient and/or a temperature coefficient thereof is zero or close to zero.

Thus, when a bias voltage or a temperature of the third capacitor changes, a capacitance value of the third capacitor does not change or changes slightly, thereby effectively ensuring the performance of the capacitive apparatus.

In some possible embodiments, the first dielectric layer includes a fifth silicon dioxide (SiO₂) layer and a sixth SiO₂ layer, and the second dielectric layer includes a second hafnium dioxide (HfO₂) layer, where the second HfO₂ layer is disposed between the fifth SiO₂ layer and the sixth SiO₂ layer.

In some possible embodiments, the at least one capacitor is at least one capacitor formed by a laminated structure.

The laminated structure is provided with layers with different temperature coefficients and/or voltage coefficients, so that when the laminated structure is regarded as a whole, a voltage coefficient and/or a temperature coefficient thereof may be zero or close to zero, thereby ensuring the performance of the capacitive apparatus.

In some possible embodiments, the laminated structure includes:

a plurality of dielectric layers and at least one conductive layer that are disposed above the substrate;

where the plurality of dielectric layers and the at least one conductive layer form a structure that a dielectric layer and a conductive layer are adjacent to each other.

In some possible embodiments, the substrate is a conductive substrate, or a surface of the substrate close to the laminated structure is provided with a conductive region with a resistivity lower than a preset threshold value, and a bottom layer of the laminated structure close to the substrate is a dielectric layer in the plurality of dielectric layers.

In some possible embodiments, the substrate is an insulating substrate, and a bottom layer of the laminated structure close to the substrate is a conductive layer in the at least one conductive layer.

In some possible embodiments, a surface of the substrate close to the laminated structure is provided with at least one groove, and at least a portion of the laminated structure is disposed in the at least one groove.

In some possible embodiments, a bottom conductive layer of the at least one conductive layer close to the substrate or a bottom dielectric layer of the plurality of dielectric layers close to the substrate forms at least one of following structures:

a trench structure, a pillar structure, or a wall structure.

In a second aspect, a method for producing a capacitive apparatus is provided, including:

producing at least one capacitor;

where the at least one capacitor includes at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient.

In some possible embodiments, the positive voltage coefficient of the first dielectric layer and the negative voltage coefficient of the second dielectric layer enable a voltage coefficient of the at least one capacitor to be zero or close to zero; and/or the positive temperature coefficient of the first dielectric layer and the negative temperature coefficient of the second dielectric layer enable a temperature coefficient of the at least one capacitor to be zero or close to zero.

In some possible embodiments, the producing at least one capacitor includes:

producing at least two capacitors connected in parallel;

where the at least two capacitors include at least one first capacitor and at least one second capacitor, and the first capacitor has a positive voltage coefficient and the second capacitor has a negative voltage coefficient, so that a voltage coefficient of the at least two capacitors is zero or close to zero; and/or the first capacitor has a positive temperature coefficient and the second capacitor has a negative temperature coefficient, so that a temperature coefficient of the at least two capacitors is zero or close to zero.

In some possible embodiments, the first dielectric layer includes a first silicon dioxide (SiO₂) layer, a second SiO₂ layer and a first hafnium oxide (HfO₂) layer, where the first HfO₂ layer is disposed between the first SiO₂ layer and the second SiO₂ layer; and the second dielectric layer includes a third SiO₂ layer, a fourth SiO₂ layer and an yttrium oxide (Y₂O₃) layer, where the Y₂O₃ layer is disposed between the third SiO₂ layer and the fourth SiO₂ layer.

In some possible embodiments, a number of the at least one first capacitor is equal to a number of the at least one second capacitor.

In some possible embodiments, the producing at least one capacitor includes:

producing a third capacitor, where dielectric layers of the third capacitor include the first dielectric layer and the second dielectric layer, so that a voltage coefficient and/or a temperature coefficient of the third capacitor is zero or close to zero.

In some possible embodiments, the first dielectric layer includes a fifth silicon dioxide (SiO₂) layer and a sixth SiO₂ layer, and the second dielectric layer includes a second hafnium dioxide (HfO₂) layer, where the second HfO₂ layer is disposed between the fifth SiO₂ layer and the sixth SiO₂ layer.

In some possible embodiments, the at least one capacitor is at least one capacitor formed by a laminated structure.

In some possible embodiments, the producing at least one capacitor includes:

producing a plurality of dielectric layers and at least one conductive layer that are disposed above a substrate;

where the plurality of dielectric layers and the at least one conductive layer form a structure that a dielectric layer and a conductive layer are adjacent to each other.

In some possible embodiments, the substrate is a conductive substrate, or a surface of the substrate close to the laminated structure is provided with a conductive region with a resistivity lower than a preset threshold value, and a bottom layer of the laminated structure close to the substrate is a dielectric layer in the plurality of dielectric layers.

In some possible embodiments, the substrate is an insulating substrate, and a bottom layer of the laminated structure close to the substrate is a conductive layer in the at least one conductive layer.

In some possible embodiments, a surface of the substrate close to the laminated structure is provided with at least one groove, and at least a portion of the laminated structure is disposed in the at least one groove.

In some possible embodiments, a bottom conductive layer of the at least one conductive layer close to the substrate or a bottom dielectric layer of the plurality of dielectric layers close to the substrate forms at least one of following structures:

a trench structure, a pillar structure, or a wall structure.

### BRIEF DESCRIPTION OF THE DRAWINGS

FIG. 1 is a schematic block diagram of a capacitive apparatus according to an embodiment of the present disclosure.

FIG. 2 is an equivalent circuit diagram of two capacitors connected in parallel according to an embodiment of the present disclosure.

FIG. 3 is a schematic diagram of a curve of a capacitance value of a capacitor changing with a voltage value.

FIGS. 4 to 5 are schematic block diagrams of modified structures of the capacitive apparatus shown in FIG. 1.

FIGS. 6 to 11 are schematic flow charts of a method for producing the capacitive apparatus shown in FIG. 1 according to an embodiment of the present disclosure.

### DESCRIPTION OF EMBODIMENTS

Technical solutions in embodiments of the present disclosure will be described hereinafter with reference to the accompanying drawings.

It should be understood that a capacitive apparatus of an embodiment of the present disclosure may play a role of bypassing, filtering, decoupling, or the like in a circuit.

The capacitive apparatus described in the embodiment of the present disclosure may be a 3D silicon capacitor, which may be a capacitor processed by semiconductor wafer processing technology.

Compared with a multilayer ceramic capacitor (Multilayer ceramic capacitor, MLCC), the 3D silicon capacitor has advantages of small size, high precision, strong stability, and long lifetime. In a processing flow of the 3D silicon capacitor, a 3D structure with a high depth-to-width ratio such as a via (Via), a trench (Trench), a pillar (Pillar) shape, a wall (Wall) shape, or the like is required to be first processed on a wafer or substrate, and then an insulating film and a low-resistivity conductive material are deposited on a surface of the 3D structure to produce a lower electrode, a dielectric layer and an upper electrode of the capacitor, sequentially.

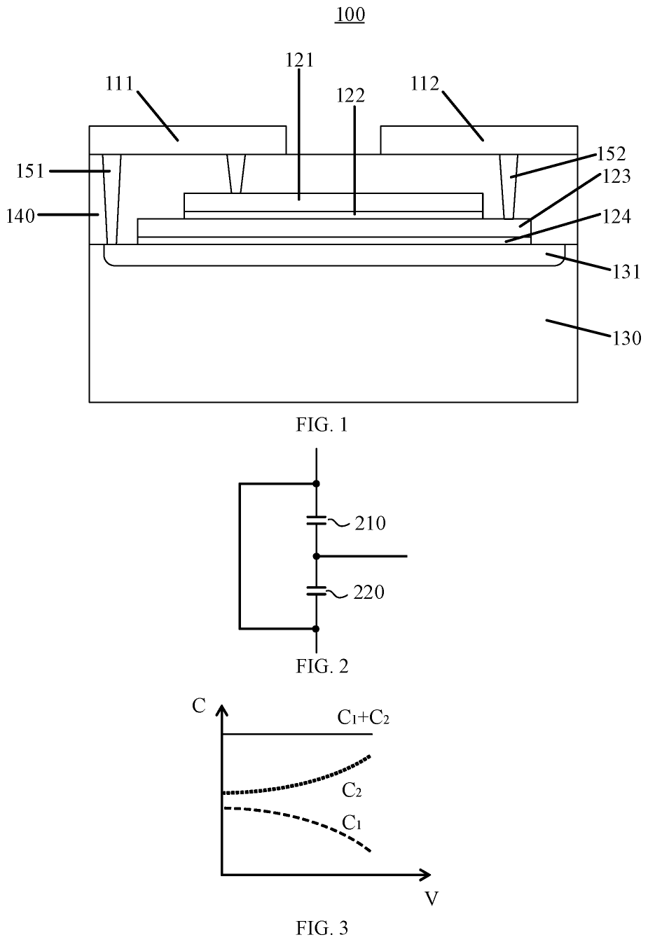

Hereinafter, a capacitive apparatus and a method for producing the same according to the present disclosure will be introduced in detail with reference to FIGS. 1 to 11.

It should be noted that, for convenience of description, in the embodiments of the present disclosure, the same reference numeral represents the same component, and a detailed explanation for the same component is omitted in different embodiments for the sake of brevity. It should be understood that dimensions such as thicknesses, lengths and widths of various components in embodiments of the present disclosure shown in the drawings, as well as dimensions of the overall thickness, length and width of an integrated apparatus are merely illustrative, and should not constitute any limitation to the present disclosure.

In addition, to facilitate understanding, in the embodiments shown below, for structures shown in different embodiments, the same structure is denoted by the same reference number, and a detailed explanation for the same structure is omitted for the sake of brevity.

Embodiments of the present disclosure provide a capacitive apparatus and a method for producing the same, which could reduce a voltage coefficient and/or a temperature coefficient of the capacitor.

Optionally, the capacitive apparatus may include at least one capacitor.

The at least one capacitor includes at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient.

That is, the voltage coefficient of the first dielectric layer of a first capacitor cancels out the voltage coefficient of the second dielectric layer of a second capacitor and/or the temperature coefficient of the first dielectric layer of the first capacitor cancels out the temperature coefficient of the second dielectric layer of the second capacitor, so that when the at least two capacitors connected in parallel are regarded as a whole, a voltage coefficient and/or a temperature coefficient thereof is zero or close to zero.

Thus, when a bias voltage or a temperature of the at least two capacitors changes, a capacitance value thereof does not change or changes slightly, thereby effectively ensuring the performance of the capacitive apparatus.

In other words, the positive voltage coefficient of the first dielectric layer and the negative voltage coefficient of the second dielectric layer enable a voltage coefficient of the at least one capacitor to be zero or close to zero; and/or the positive temperature coefficient of the first dielectric layer and the negative temperature coefficient of the second dielectric layer enable a temperature coefficient of the at least one capacitor to be zero or close to zero.

It should be understood that the coefficient close to zero may refer to that the coefficient is substantively zero, and at this time, when the bias voltage and/or temperature of the capacitor changes, the capacitance value thereof does not change or changes slightly.

In some embodiments of the present disclosure, the at least one capacitor may include:

at least two capacitors connected in parallel;

where the at least two capacitors include at least one first capacitor and at least one second capacitor, and the first capacitor has a positive voltage coefficient and the second capacitor has a negative voltage coefficient, so that a voltage coefficient of the at least two capacitors is zero or close to zero; and/or the first capacitor has a positive temperature coefficient and the second capacitor has a negative temperature coefficient, so that a temperature coefficient of the at least two capacitors is zero or close to zero.

FIG. 1 is a schematic block diagram of a capacitive apparatus 100 according to an embodiment of the present disclosure.

Referring to FIG. 1, the capacitive apparatus 100 may include a first capacitor and a second capacitor, where the first capacitor may be formed by a conductive region 131 formed on an upper surface of a substrate 130, a first dielectric layer 124 and a first conductive layer 123, and the second capacitor may be formed by the first conductive layer 123, a second dielectric layer 122 and a second conductive layer 121. Further, a first electrode 111 is electrically connected to the conductive region 131 and the second conductive layer 121 through a first via 151 in an insulating layer 140, and a second electrode 112 is electrically connected to the first conductive layer 123 through a second via 152 in the insulating layer 140, so that the first capacitor is connected in parallel with the second capacitor, thereby forming a large capacitor.

The first dielectric layer 124 may be formed of a material with a positive voltage coefficient, and the second dielectric layer 122 may be formed of a material with a negative voltage coefficient, so that a voltage coefficient of the capacitive apparatus 100 is zero or close to zero; and/or, the first dielectric layer 124 may be formed of a material with a positive temperature coefficient, and the second dielectric layer 122 may be formed of a material with a negative temperature coefficient, so that a temperature coefficient of the at least two capacitors is zero or close to zero. FIG. 2 is an equivalent circuit diagram of the capacitive apparatus 100 shown in FIG. 1.

Referring to FIG. 2, the capacitive apparatus 100 may include a first capacitor 210 and a second capacitor 220 connected in parallel.

FIG. 3 is a schematic diagram of a curve of a capacitance value of a capacitor changing with a voltage value.

Referring to FIG. 3, it is assumed that a capacitance value C₁ of the first capacitor 210 increases with the increase of a bias voltage V across both ends thereof, and a capacitance value C₂ of the second capacitor 220 decreases with the increase of a bias voltage V across both ends thereof, however when the capacitive apparatus 100 is regarded as a whole, a capacitance value thereof does not change with a bias voltage V across both ends thereof, thus effectively ensuring the performance of the capacitive apparatus.

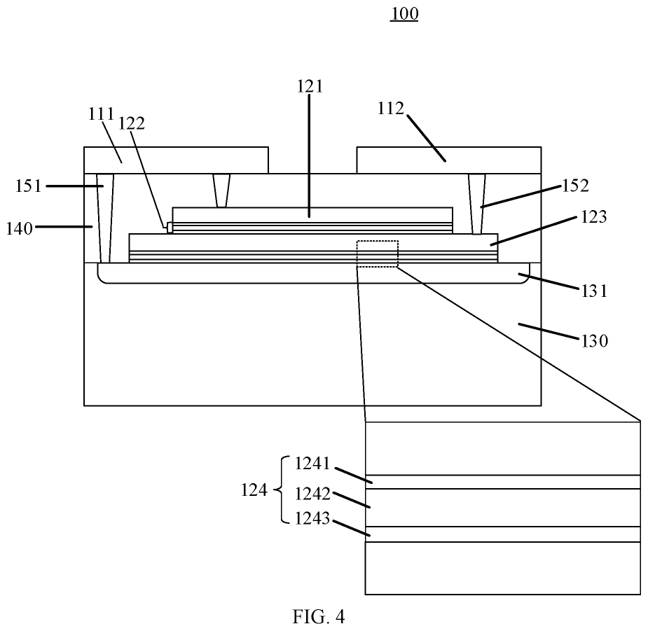

FIG. 4 is a schematic structural diagram of a modified structure of the capacitive apparatus 100 shown in FIG. 1.

Referring to FIG. 4, the first dielectric layer 124 may include a first silicon dioxide SiO₂ layer 1241, a second SiO₂ layer 1243 and a first hafnium oxide HfO₂ layer 1242, where the first HfO₂ layer is disposed between the first SiO₂ layer and the second SiO₂ layer. Similarly, the second dielectric layer 122 may include a third SiO₂ layer, a fourth SiO₂ layer and an yttrium oxide Y₂O₃ layer, where the Y₂O₃ layer is disposed between the third SiO₂ layer and the fourth SiO₂ layer.

As a voltage coefficient of Y₂O₃ is negative and a voltage coefficient of HfO₂ is positive, Y₂O₃ and HfO₂ are respectively used as dielectric layers in two capacitors, so that when the two capacitors are regarded as a whole, a voltage coefficient thereof may be zero or close to zero.

Thus, when a bias voltage or a temperature of the two capacitors changes, a capacitance value thereof does not change or changes slightly, thereby effectively ensuring the performance of the capacitive apparatus.

In addition, Y₂O₃ and HfO₂ belong to high dielectric constant (high-k) materials, and a band gap thereof is small, which easily causes leakage of the capacitor. Therefore, SiO₂ with a wide band gap is placed on upper and lower surfaces of the high-k materials, which could reduce the leakage of the capacitor and ensure the comprehensive performance of the capacitor.

Further, the capacitive apparatus 100 may be formed by an even number of capacitors connected in parallel. For example, a number of the at least one first capacitor is equal to a number of the at least one second capacitor to ensure that the voltage coefficient and/or the temperature coefficient of the capacitive apparatus 100 is zero or close to zero. Of course, the capacitive apparatus 100 may also be formed by an odd number of capacitors connected in parallel, which is not specifically limited in the embodiment of the present disclosure.

In some other embodiments of the present disclosure, the at least one capacitor includes:

a third capacitor, where dielectric layers of the third capacitor include the first dielectric layer and the second dielectric layer, so that a voltage coefficient and/or a temperature coefficient of the third capacitor is zero or close to zero.

That is, the voltage coefficient of the first dielectric layer cancels out the voltage coefficient of the second dielectric layer, and/or the temperature coefficient of the first dielectric layer cancels out the temperature coefficient of the second dielectric layer, so that when the dielectric layers of the third capacitor are regarded as a whole, a voltage coefficient and/or a temperature coefficient thereof is zero or close to zero.

Thus, when a bias voltage or a temperature of the third capacitor changes, a capacitance value of the third capacitor does not change or changes slightly, thereby effectively ensuring the performance of the capacitive apparatus.

For example, the first dielectric layer includes a fifth SiO₂ layer and a sixth SiO₂ layer, and the second dielectric layer includes a second HfO₂ layer, where the second HfO₂ layer is disposed between the fifth SiO₂ layer and the sixth SiO₂ layer.

As a voltage coefficient of SiO₂ is negative and a voltage coefficient of HfO₂ is positive, a laminated layer formed by SiO₂ and HfO₂ is used as a dielectric layer of the third capacitor, so that a voltage coefficient of the third capacitor may be zero or close to zero.

In addition, HfO₂ belongs to a high dielectric constant (high-k) material, and a band gap thereof is small, which easily causes excessive leakage of the capacitor. Therefore, SiO₂ with a wide band gap is placed on upper and lower surfaces of the HfO₂ layer, which could reduce the leakage of the capacitor and ensure the comprehensive performance of the capacitor.

Of course, in other alternative embodiments, the foregoing at least two capacitors and the foregoing third capacitor may be connected in parallel to form a capacitive apparatus with a large capacitance value, which is not specifically limited in the embodiment of the present disclosure.

In some embodiments of the present disclosure, the at least one capacitor is at least one capacitor formed by a laminated structure.

The laminated structure is provided with layers with different temperature coefficients and/or voltage coefficients, so that when the laminated structure is regarded as a whole, a voltage coefficient and/or a temperature coefficient thereof may be zero or close to zero, thereby ensuring the performance of the capacitive apparatus.

In some embodiments of the present disclosure, the laminated structure may include a plurality of dielectric layers and at least one conductive layer that are disposed over a substrate, where the plurality of dielectric layers and the at least one conductive layer form a structure that a dielectric layer and a conductive layer are adjacent to each other.

For example, the plurality of dielectric layers includes at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient.

In some embodiments of the present disclosure, the substrate is a conductive substrate, or a surface of the substrate close to the laminated structure is provided with a conductive region with a resistivity lower than a preset threshold value, and a bottom layer of the laminated structure close to the substrate is a dielectric layer in the plurality of dielectric layers.

In some embodiments of the present disclosure, the substrate is an insulating substrate, and a bottom layer of the laminated structure close to the substrate is a conductive layer in the at least one conductive layer.

In some embodiments of the present disclosure, a surface of the substrate close to the laminated structure is provided with at least one groove, and at least a portion of the laminated structure is disposed in the at least one groove.

In some embodiments of the present disclosure, a bottom conductive layer of the at least one conductive layer close to the substrate or a bottom dielectric layer of the plurality of dielectric layers close to the substrate forms at least one of following structures:

a trench structure, a pillar structure, or a wall structure.

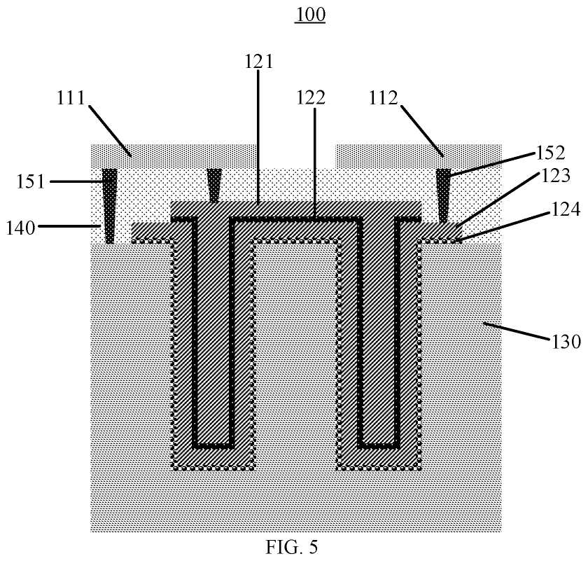

FIG. 5 is a schematic diagram of another modified structure of the capacitive apparatus 100 shown in FIG. 1.

Referring to FIG. 5, the capacitive apparatus 100 includes a conductive substrate 130, and an upper surface of the conductive substrate 130 extends downward to form at least one groove (for example, two grooves shown in FIG. 5). The capacitive apparatus 100 may include a first capacitor and a second capacitor, where the first capacitor may be formed by the conductive substrate 130, a first dielectric layer 124 and a first conductive layer 123, and the second capacitor may be formed by the first conductive layer 123, a second dielectric layer 122 and a second conductive layer 121. Further, a first electrode 111 is electrically connected to the conductive substrate 130 and the second conductive layer 121 through a first via 151 in an insulating layer 140, and a second electrode 112 is electrically connected to the first conductive layer 123 through a second via 152 in the insulating layer 140, so that the first capacitor is connected in parallel with the second capacitor, thereby forming a large capacitor.

The present disclosure also provides a method for producing a capacitive apparatus, which could reduce a voltage coefficient and/or a temperature coefficient of the capacitive apparatus.

In some embodiments of the present disclosure, the at least one capacitor is produced.

The at least one capacitor includes at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient.

In some embodiments of the present disclosure, the positive voltage coefficient of the first dielectric layer and the negative voltage coefficient of the second dielectric layer enable a voltage coefficient of the at least one capacitor to be zero or close to zero; and/or the positive temperature coefficient of the first dielectric layer and the negative temperature coefficient of the second dielectric layer enable a temperature coefficient of the at least one capacitor to be zero or close to zero.

In some embodiments of the present disclosure, the producing at least one capacitor includes:

producing at least two capacitors connected in parallel;

where the at least two capacitors include at least one first capacitor and at least one second capacitor, and the first capacitor has a positive voltage coefficient and the second capacitor has a negative voltage coefficient, so that a voltage coefficient of the at least two capacitors is zero or close to zero; and/or the first capacitor has a positive temperature coefficient and the second capacitor has a negative temperature coefficient, so that a temperature coefficient of the at least two capacitors is zero or close to zero.

In some embodiments of the present disclosure, the first dielectric layer includes a first silicon dioxide SiO₂ layer, a second SiO₂ layer and a first hafnium oxide HfO₂ layer, where the first HfO₂ layer is disposed between the first SiO₂ layer and the second SiO₂ layer; and the second dielectric layer includes a third SiO₂ layer, a fourth SiO₂ layer and an yttrium oxide Y₂O₃ layer, where the Y₂O₃ layer is disposed between the third SiO₂ layer and the fourth SiO₂ layer.

In some embodiments of the present disclosure, a number of the at least one first capacitor is equal to a number of the at least one second capacitor.

In some embodiments of the present disclosure, the producing at least one capacitor includes:

producing a third capacitor, where dielectric layers of the third capacitor include the first dielectric layer and the second dielectric layer, so that a voltage coefficient and/or a temperature coefficient of the third capacitor is zero or close to zero.

In some embodiments of the present disclosure, the first dielectric layer includes a fifth silicon dioxide SiO₂ layer and a sixth SiO₂ layer, and the second dielectric layer includes a second hafnium dioxide HfO₂ layer, where the second HfO₂ layer is disposed between the fifth SiO₂ layer and the sixth SiO₂ layer.

In some embodiments of the present disclosure, the at least one capacitor is at least one capacitor formed by a laminated structure.

In some embodiments of the present disclosure, the producing at least one capacitor includes:

producing a plurality of dielectric layers and at least one conductive layer that are disposed above a substrate;

where the plurality of dielectric layers and the at least one conductive layer form a structure that a dielectric layer and a conductive layer are adjacent to each other.

In some embodiments of the present disclosure, the substrate is a conductive substrate, or a surface of the substrate close to the laminated structure is provided with a conductive region with a resistivity lower than a preset threshold value, and a bottom layer of the laminated structure close to the substrate is a dielectric layer in the plurality of dielectric layers.

In some embodiments of the present disclosure, the substrate is an insulating substrate, and a bottom layer of the laminated structure close to the substrate is a conductive layer in the at least one conductive layer.

In some embodiments of the present disclosure, a surface of the substrate close to the laminated structure is provided with at least one groove, and at least a portion of the laminated structure is disposed in the at least one groove.

In some embodiments of the present disclosure, a bottom conductive layer of the at least one conductive layer close to the substrate or a bottom dielectric layer of the plurality of dielectric layers close to the substrate forms at least one of following structures:

a trench structure, a pillar structure, or a wall structure.

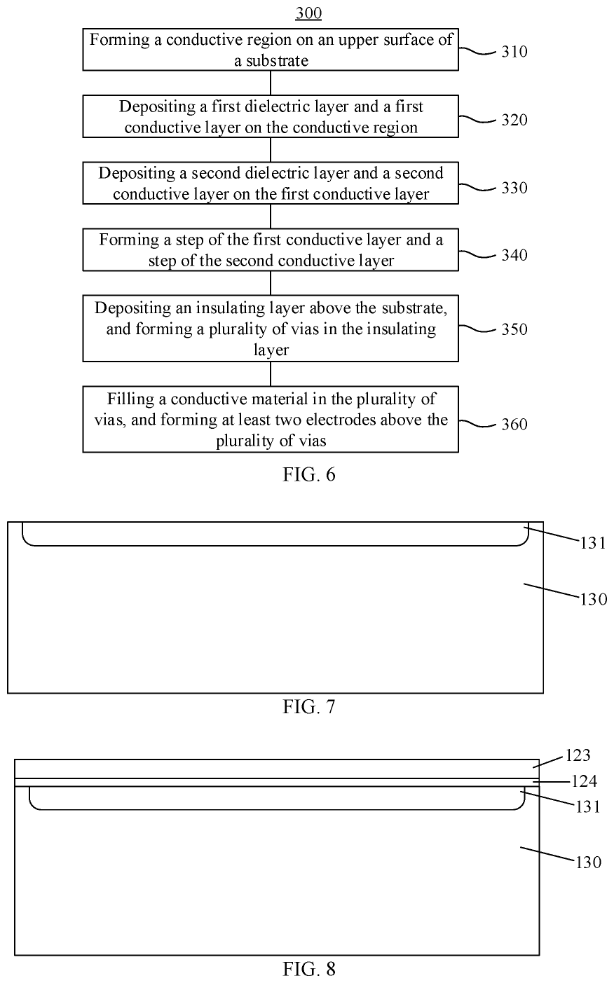

FIG. 6 is a schematic flow chart of a method 300 for producing a capacitive apparatus 100 according to an embodiment of the present disclosure. FIGS. 7 to 11 are schematic block diagrams of respective structures formed in a process of producing the capacitive apparatus 100. A method for producing a capacitive apparatus according to an embodiment of the present disclosure will be exemplarily illustrated with reference to FIGS. 6 to 11.

Referring to FIG. 6, the method 300 may include:

S310, a conductive region is formed on an upper surface of a substrate.

For example, referring to FIG. 7, a silicon wafer may be selected as a substrate 130, and doping is performed on a local region of an upper surface of the substrate 130 to form a low-resistivity conductive region 131. Of course, in other alternative embodiments, a conductive substrate may also be directly used, or doping may also be performed on an entire upper surface of the substrate, which is not specifically limited in an embodiment of the present disclosure.

The substrate 130 may be a semiconductor substrate, a glass substrate, or an organic substrate whose surface is provided with a low-resistivity conductive layer. A material of the semiconductor substrate may be silicon, germanium, or III-V elements such as silicon carbide (SiC), gallium nitride (GaN), gallium arsenide (GaAs), or the like), or a combination of the foregoing different materials. The semiconductor substrate may also include an epitaxial layer structure of the substrate for insulating the substrate, such as a silicon-on-insulator (SOI) structure. The substrate 130 may be a whole piece of the wafer or a portion cut from the wafer.

S320, a first dielectric layer and a first conductive layer are deposited on the conductive region.

For example, referring to FIG. 8, a first dielectric layer 124 and a first conductive layer 123 are deposited on the conductive region 131, where the first dielectric layer 124 may have a negative voltage (temperature) coefficient or a positive voltage (temperature) coefficient.

A material of the first conductive layer 123 may be formed of a low-resistivity conductive material, which may be, for example, heavily doped polysilicon, a carbon material, or various metals such as aluminum (Al), tungsten (W), copper (Cu), titanium (Ti), tantalum (Ta), platinum (Pt), ruthenium (Ru), iridium (Ir), rhodium (Rh), or the like, or may be a low-resistivity compound such as titanium nitride and tantalum nitride, or a laminated layer or combination of the foregoing several conductive materials, which is not specifically limited in the embodiment of the present disclosure.

S330, a second dielectric layer and a second conductive layer are deposited on the first conductive layer.

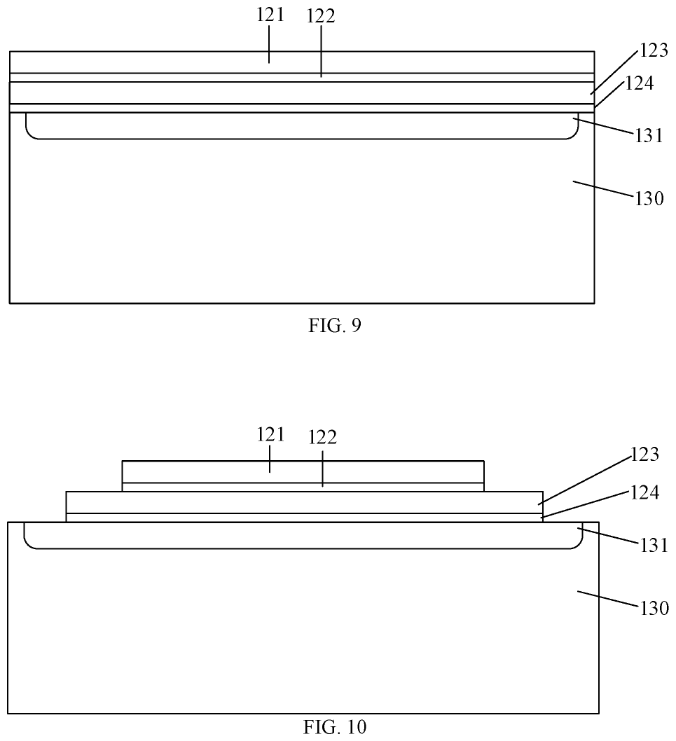

For example, referring to FIG. 9, a second dielectric layer 122 and a second conductive layer 121 are deposited on the first conductive layer 123, and when the first dielectric layer 124 has a negative voltage (temperature) coefficient, the second dielectric layer 122 has a positive voltage (temperature) coefficient; and when the first dielectric layer 124 has a positive voltage (temperature) coefficient, the second dielectric layer 122 has a negative voltage (temperature) coefficient.

A material of the second conductive layer 121 and a material of the first conductive layer 123 may be the same or different, which is not specifically limited in the present disclosure.

S340, a step of the first conductive layer and a step of the second conductive layer are formed.

For example, referring to FIG. 10, the steps of the first conductive layer 123 and the second conductive layer 121 may be formed by a photolithography process, and the low-resistivity conductive region 131 of the substrate 130 is exposed.

S350, an insulating layer is deposited above the substrate, and a plurality of vias are formed in the insulating layer.

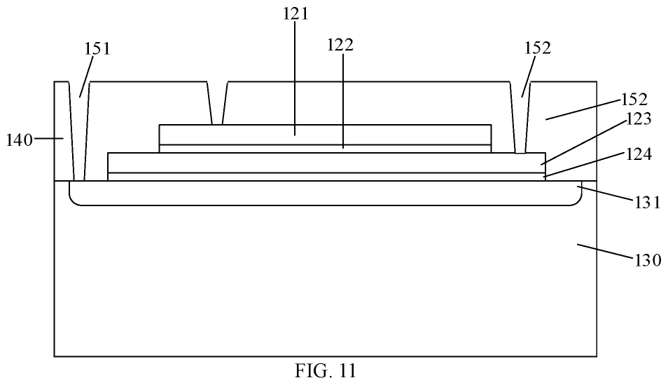

For example, referring to FIG. 11, an insulating layer 140 may be deposited above the substrate 130 as an interlayer dielectric layer for covering the substrate 130 and respective conductive layers. Further, a photolithography process may be combined with an etching process to form at least one first via 151 and at least one second via 152, where the first via 151 is configured to expose the conductive region 131 and the second conductive layer 121, and the second via 152 is configured to expose the first conductive layer 123.

A material of the first insulating layer 140 may be an organic polymer material, such as polyimide, parylene, benzocyclobutene (BCB), or the like, it may also be some inorganic materials, such as spin on glass (SOG), undoped silicon glass (USG), boro-silicate glass (BSG), phospho-silicate glass (PSG), boro-phospho-silicate glass (BPSG), silicon oxide synthesized by tetraethyl orthosilicate (TEOS), silicon oxide, silicon nitride and ceramic; and it may also be a laminated layer or combination of the foregoing materials.

S360, a conductive material is filled in the plurality of vias, and at least two electrodes are formed above the plurality of vias.

For example, referring to FIG. 1, a conductive material is filled in the first via 151 and the second via 152 to form conductive channels. Further, a first electrode 111 and a second electrode 112 are respectively produced above the first via 151 and the second via 152, where the first electrode 111 is connected to the low resistivity-conductive region 131 of the substrate 130 and the second conductive layer 121 through a conductive channel formed by the first via 151, and the second electrode 112 is electrically connected to the first conductive layer 123 through a conductive channel formed by the second via 152.

It should be understood that the etching process may include at least one of the following processes:

a dry etching process, a wet etching process or a laser etching process.

Further, the dry etching process may include at least one of the following etching processes: reactive ion etching, ion beam etching, or the like. A chemical raw material of the wet etching process may include, but is not limited to, an etching solution containing hydrofluoric acid. In some embodiments of the present disclosure, an etching method combining dry etching with wet etching is adopted, or an etching method combining laser etching with wet etching is adopted, which could effectively ensure the etched shape and the flatness of the bottom surface, or the like.

The deposition process includes, but is not limited to:

a physical vapor deposition (PVD) process and/or a chemical vapor deposition (CVD) process. For example, thermal oxidation, plasma enhanced chemical vapor deposition (PECVD), low pressure chemical vapor deposition (LPCVD), atomic layer deposition (ALD), electroplating, spin coating or spray coating, or the like.

It should also be understood that the method embodiment and the product embodiment may correspond to each other, and similar descriptions may refer to the product embodiment. For the sake of brevity, they will not be repeatedly described here.

It should also be understood that FIGS. 1 to 5 are only examples of the present disclosure, and should not be understood as limitation to the present disclosure.

For example, in other alternative embodiments, the process of producing the conductive region may be directly omitted. That is, the dielectric layer is directly produced on the conductive substrate.

It should also be understood that, each embodiment of the method 300 for producing the capacitive apparatus listed above may be executed by a robot or numerical control machine. The device software or process for executing the method 300 may execute the foregoing method 300 by executing the computer program code stored in the memory.

It shall be noted that each embodiment described in the present disclosure and/or the technical features in each embodiment can be combined with each other arbitrarily in the case of no conflict, and the technical solutions obtained after combination should also fall into the protection scope of the present disclosure.

It should be understood that sequence numbers of the foregoing processes do not mean execution sequences in various embodiments of the present disclosure. The execution sequences of the processes should be determined according to functions and internal logic of the processes, and should not be construed as any limitation on the implementation processes of the embodiments of the present disclosure.

An ordinary person skilled in the art may be aware that the preparation method described in conjunction with the embodiments disclosed herein can be implemented by electronic hardware or a combination of computer software and electronic hardware. Whether these functions are implemented in the form of hardware or software depends upon a particular application of the technical solutions and constraint conditions of design. A person skilled in the art may use different methods to implement the described functions for each particular application, but it should not be considered that the implementation goes beyond the scope of the present disclosure.

In several embodiments provided by the present disclosure, it should be understood that the disclosed integrated apparatus, the components in the integrated apparatus and the method for producing the integrated apparatus may be realized in other manners. For example, the embodiments of the integrated apparatus described above are only exemplary. For example, the division of layers is just a division of logical functions, and there may be other division manners for practical implementations. For example, multiple layers or devices may be combined or integrated, and for example, the upper plate and the active material layer may be combined into one layer. Or some features (such as the active material layer) may be omitted or not produced.

The foregoing descriptions are merely specific embodiments of the present disclosure, however, the protection scope of the present disclosure is not limited thereto, persons skilled in the art who are familiar with the art could readily think of variations or substitutions within the technical scope disclosed by the present disclosure, and these variations or substitutions shall fall within the protection scope of the present disclosure. Therefore, the protection scope of the present disclosure shall be subject to the protection scope of the claims.

What is claimed is:

1. A capacitive apparatus, comprising:
at least one capacitor;
wherein the at least one capacitor comprises at least one first dielectric layer and at least one second dielectric layer, the first dielectric layer has a positive voltage coefficient and the second dielectric layer has a negative voltage coefficient; and/or the first dielectric layer has a positive temperature coefficient and the second dielectric layer has a negative temperature coefficient, wherein the positive voltage coefficient of the first dielectric layer and the negative voltage coefficient of the second dielectric layer enable a voltage coefficient of the at least one capacitor to be zero or close to zero, the positive temperature coefficient of the first dielectric layer and the negative temperature coefficient of the second dielectric layer enable a temperature coefficient of the at least one capacitor to be zero or close to zero.

2. The capacitive apparatus according to claim 1, wherein the at least one capacitor comprises:
a first capacitor comprising the first dielectric layer;
a second capacitor comprising the second dielectric layer, wherein the first capacitor and the second capacitor are connected in parallel.

3. The capacitive apparatus according to claim 2, wherein the first dielectric layer comprises a first hafnium oxide (HfO₂) layer, and the second dielectric layer comprises an yttrium oxide (Y₂O₃) layer.

4. The capacitive apparatus according to claim 3, wherein the first dielectric layer further comprises a first silicon dioxide (SiO₂) layer, and a second SiO₂ layer, wherein the first HfO₂ layer is disposed between the first SiO₂ layer and the second SiO₂ layer.

5. The capacitive apparatus according to claim 4, wherein the second dielectric layer further comprises a third SiO₂ layer, a fourth SiO₂ layer, wherein the Y₂O₃ layer is disposed between the third SiO₂ layer and the fourth SiO₂ layer.

6. The capacitive apparatus according to claim 1, wherein the at least one capacitor comprises:
a single capacitor comprising the first dielectric layer and the second dielectric layer.

7. The capacitive apparatus according to claim 6, wherein the second dielectric layer comprises two SiO₂ layers, and the first dielectric layer comprises a second HfO₂ layer, wherein the second HfO₂ layer is disposed between the two SiO₂ layers.

8. The capacitive apparatus according to claim 1, wherein the at least on capacitor further comprises:
a substrate comprising a first surface; and
a plurality of conductive layers disposed on the substrate, the substrate and the plurality of conductive layers are separated by the first dielectric layer and the second dielectric layer.

9. The capacitive apparatus according to claim 8, wherein the substrate is a conductive substrate, or the first surface of the substrate is provided with a conductive region with a resistivity lower than a preset threshold value, and one of the first dielectric layer and the second dielectric layer is contact with the first surface of the substrate.

10. The capacitive apparatus according to claim 9, wherein the first surface of the substrate is provided with at least one groove, and at least a portion of the conductive layers, the first dielectric layer and the second dielectric layer are disposed in the at least one groove.

11. The capacitive apparatus according to claim 8, wherein the substrate is an insulating substrate, and one of the conductive layers is contact with the first surface of the substrate.

12. A method for producing a capacitive apparatus, comprising:
producing at least one capacitor;
wherein the at least one capacitor comprises at least one first dielectric layer and at least one second dielectric layer, the first dielectric layer has a positive voltage coefficient and the second dielectric layer has a negative voltage coefficient, the positive voltage coefficient of the first dielectric layer and the negative voltage coefficient of the second dielectric layer enable a voltage coefficient of the at least one capacitor to be zero or close to zero; and/or the first dielectric layer has a positive temperature coefficient and the second dielectric layer has a negative temperature coefficient, the positive temperature coefficient of the first dielectric layer and the negative temperature coefficient of the second dielectric layer enable a temperature coefficient of the at least one capacitor to be zero or close to zero.

13. The method according to claim 12, wherein the producing at least one capacitor comprises:
producing at least two capacitors connected in parallel;
wherein the at least two capacitors comprise at least one first capacitor and at least one second capacitor, wherein the first capacitor comprises the first dielectric layer and the second capacitor comprises the second dielectric layer.

14. The method according to claim 13, wherein the first dielectric layer comprises a first SiO₂ layer, a second SiO₂ layer and a first HfO₂ layer, wherein the first HfO₂ layer is disposed between the first SiO₂ layer and the second SiO₂ layer; and the second dielectric layer comprises a third SiO₂ layer, a fourth SiO₂ layer and a Y₂O₃ layer, wherein the Y₂O₃ layer is disposed between the third SiO₂ layer and the fourth SiO₂ layer.

15. The method according to claim 14, wherein the producing at least one capacitor further comprises:
producing at least one conductive layer on a substrate, wherein the substrate and the at least one conductive layer are separated by the first dielectric layer and the second dielectric layer.

16. The method according to claim 15, wherein a surface of substrate is contact with one of the first dielectric layer and the second dielectric layer, and the substrate is a conductive substrate or the surface of the substrate is provided with a conductive region with a resistivity lower than a preset threshold value.

17. The method according to claim 15, wherein the substrate is an insulating substrate, and one of the at least one conductive layer is contact with the substrate.

18. The method according to claim 15, wherein a surface of the substrate is provided with at least one groove, and the at least one conductive layer, the first dielectric layer and the second dielectric layer are disposed in the at least one groove.

19. The method according to claim 12, wherein the producing at least one capacitor comprises:
producing a single capacitor, wherein the single capacitor comprises the first dielectric layer and the second dielectric layer.

20. The method according to claim 19, wherein the second dielectric layer comprises a fifth SiO₂ layer and a sixth SiO₂ layer, and the first dielectric layer comprises a second HfO₂ layer, wherein the second HfO₂ layer is disposed between the fifth SiO₂ layer and the sixth SiO₂ layer.
